(19) United States
(12) Patent Application Publication
(10) Pub. No.: US 2002/0094094 A1
(43) Pub. Date: Jul. 18, 2002

(54) Headset device

(75) Inventor: Byung-Chun Shin, Seoul (KR)

Correspondence Address: John P. White, Cooper & Dunham LLP, 1185 Avenue of the Americas, New York, NY, 10036, US

(73) Assignee: Seo Won K-Tec., Inc.

(21) Appl. No.: 09/834,549

(22) Filed: Apr. 13, 2001

(30) Foreign Application Priority Data
Jan. 17, 2001 (KR) 10-2001-2730

(51) Int. Cl. H03G 3/00; H04R 25/00

(52) U.S. Cl. 381/104; 381/309; 381/370; 381/374

(57) ABSTRACT

A headset device is provided with a headphone unit having head band, a pair of guide arms and a speaker unit, a microphone unit connected to one side of the speaker unit, and a controller divided into two bodies, wherein since the pair of guide arms are adapted to be rotatably connected to the speaker unit, a position of the head band can be easily adjusted, with an auricle of the user being enclosed by the speaker unit, whereby the user can feel good to wear the headset device due to resilience and softness thereof, and wherein the headset device is capable of being used with various apparatuses such as a telephone and a computer system since the controller which can be divided into two bodies or assembled into a unit enables replacing connection terminals with various kinds of other connection terminals is used.

### FIELD OF THE INVENTION

The present invention relates to a headset device, more particularly, to a headset device capable of being used with various apparatuses such as a telephone and a computer system and having a convenience to use, wherein a position of a head band can be easily adjusted, with an auricle of the user being enclosed by a speaker unit, whereby the user can feel good to wear the headset device due to resilience and softness thereof.

### DESCRIPTION OF THE PRIOR ART

In general, a headphone is usually used to listen to music. Further, in recent days, technology on providing music files, e.g., based on MPEG 3 to a computer system and technologies on voice communication and video communication have been rapidly developed. For these reasons, a headset device incorporating therein functions of a microphone and a headphone has been widely used to enable, e.g., listening to music, working with a computer system.

Developments of the information and communication technology enables developments of technology for providing the user with various services and convenience. One of these is developments of devices and peripherals for enabling the voice and video communications using the computer system.

In enjoying listening to music and voice communication by using the computer system having a sound card or the like for generating an audio sound, a hands-free communication device connected to the sound card is needed.

By using the hands-free communication device mounted around or on the head, the user can communicate with other people with his hands kept free or he can manipulate a keyboard or other work freely.

Further, since more much people come to use the cellular phone or mobile phone due to rapid developments of the mobile communication, wishes for various hands-free communication devices are being increased due to its convenience, e.g., not to use hands.

FIG. 1 shows a perspective view of the prior art headset device for use with a computer system.

As shown, the prior art headset device of the head-supporting type includes a speaker unit 14 mounted to a guide arm 12 insertable into an end of a head band 10 for a length adjustment, a microphone unit 16 connected to the speaker unit 14 via a connecting bar 24, and a speaker connection terminal 18 and a microphone connection terminal 20 connected to the speaker unit 14 and the microphone unit 15, respectively, through cables 22.

The speaker connection terminal 18 is connected to a speaker socket of a sound card in the computer system, while the microphone connection terminal 20 being connected to a microphone socket (MIC). In this situation, the user wears the headset device on his head using the head band 10.

In use, the user adjusts the length of the guide arm 12 in order to locate the speaker unit 14 on his ear and rotates the connecting bar 24 to locate the microphone 16 near his mouth.

After these, the user has to execute programs on the computer system for controlling a sound level of the speaker unit 14 and the microphone unit 16.

Although the prior art headset device has advantages in that it allows the user to enjoy music or to make a communication with his hands kept free, the prior art headset device has several shortcomings.

The prior art headset devices has a limited use in that a headset device for use with the computer system has to be devoted to the use with computer system, i.e., it's usage can not be changed to the use with, e.g., the telephone. This is because the sockets or the connection terminals of the computer system and the telephone are different from each other and one headset device in accordance with the prior art only has one kind of connection terminal of its own.

Further, in the prior art headset devices, the speaker unit 14 has a circular shape not covering the whole ear of the user and maintained within the auricle of the ear. Furthermore, the circular speaker unit 14 is fixed to the guide arm 12 and has its orientation changed depending upon the mounting angle of the head band 10 on the head of the user.

That is, if the user changes the mounting angle of the head band 10, the speaker unit 14 maintained within the auricle of the ear has to be rotated. During the rotation, the speaker unit 14 often deviates from the desired position on the auricle, causing the user to reposition the speaker unit 14 to feel inconvenient.

In addition, the prior art headset device provides the user with discomfort such as a pain or an ache after the long period of use. It often makes the hair style of the user disordered by the head band 10.

To obviate this problem, it is recommended that the mounting angle of the head band 10 be changed frequently. However, changing the orientation or position of the head band 10 is not easy in the prior art headset device, since the position or orientation of the speaker unit 14 must be corrected at the same time.

### SUMMARY OF THE INVENTION

It is, therefore, a primary object of the invention to provide a headset device configured to allow connection terminals to be replacable with other ones appropriate to apparatus to be used.

Another object of the present invention is to provide a headset device having a head band and a speaker unit which can rotate relative to each other and capable of enclosing an auricle of an ear of the user and of coming into a slight-contact to a rear portion of the ear, not depressing the auricle, thereby not being accompanied with any pain or ache even after the long period of use.

In order to achieve the object, the present invention provides a headset device is provided with a head band having a resilience and a semi-circular shape to be mounted on a head of the user, the head band having at both ends thereof slide grooves, respectively, a pair of guide arms each having a slide bar inserted into the slide groove of the head band to allow length of the headset device to be adjusted, and a coupling bar integrally formed with the slide bar and rotatably connected to a speaker unit using a pair of protuberances which protrude from a semi-circular shape portion formed on one end of the coupling bar and opened, being inclined with respect to a horizontal plane, the pair of speaker units each having an ear cover case of an oval shape with size capable of enclosing an auricle of the user, a rotation connection connected to the guide arm and mounted to an external surface of the ear cover case, a click cover of a disk shape for guiding the rotation of the rotation connection, the click cover positioned inside the rotation connection and inserted into a circular seat formed on the external surface of the ear cover case along with the rotation connection, an ear cover having a speaker attached thereto, the speaker mounted on an inner surface of the ear cover case to be incorporated therein, and a soft cover member enclosing the ear cover made of leather or the like, and a controller having a function for controlling a sound level output to the speaker unit, and a function for controlling a sound level from a microphone, the controller divided into two portions.

In accordance with one aspect of the present invention, since the controller can be divided into a leading portion and a rear portion, i.e., the cable is partially replacable, this configuration allows the user to easily select connection terminals appropriate to the type of the socket of his newly changed sound card and replace the connection terminals with the selected one by simply changing the rear portion.

### BRIEF DESCRIPTION OF THE DRAWINGS

The above and other objects and features of the instant invention will become apparent from the following description of preferred embodiments taken in conjunction with the accompanying drawings, in which:

FIG. 1 illustrates a perspective view of the prior art headset device;

FIG. 2 illustrates a perspective view of a headset device in accordance with a preferred embodiment of the present invention;

FIG. 3a depicts a frontal elevational view of a head band of the present invention;

FIG. 3b represents a sectional view of the head band shown in FIG. 3a, taken along a line A-A;

FIGS. 4a to 4c depict a frontal elevational view and side elevational views of a guide arm of the inventive headset device, respectively;

FIG. 5 presents an exploded perspective view of a speaker unit of the inventive headset device;

FIGS. 6a through 6d depict a frontal elevational view, a side elevational view, a rear elevational view, and a sectional view of a rotation connection of the inventive headset device, respectively;

FIGS. 7a through 7c depict a frontal elevational view, a side elevational view, and a rear elevational view of a click cover of the speaker unit of the inventive headset device, respectively;

FIGS. 8a through 8c depict a frontal elevational view, a side elevational view, and a rear elevational view of an ear cover case of the inventive headset device, respectively;

FIGS. 9a through 9c depict a frontal elevational view, a top planar view, and a rear elevational view of an ear cover of the speaker unit of the inventive headset device, respectively;

FIGS. 10a and 10b show the inventive headset devices mounted on the user's head, respectively; and

FIG. 11 sets forth a perspective view of a controller in a disassembled state.

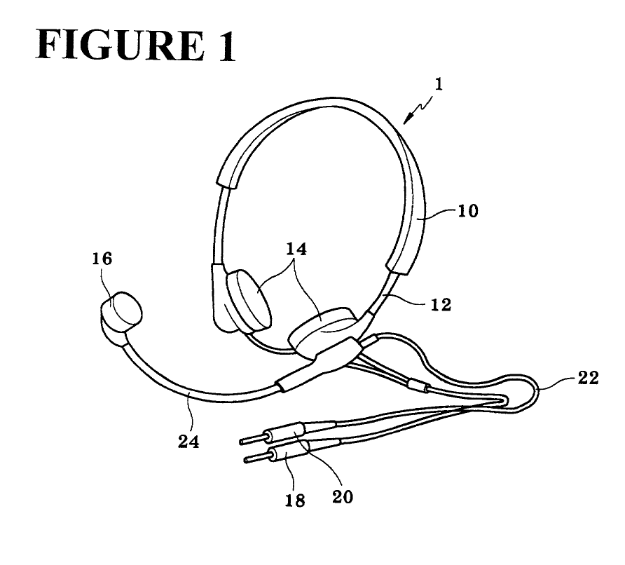

### DETAILED DESCRIPTION OF THE PREFERRED EMBODIMENTS

Preferred embodiments of the present invention are described with reference to accompanying drawings.

For a better understanding of the present invention, the configuration and the operation of the inventive headset device will be concurrently described. Further, the description will be made to one side of right and left sides of the headset device, since the two are similar in configuration to each other except a portion for a connection with a microphone unit.

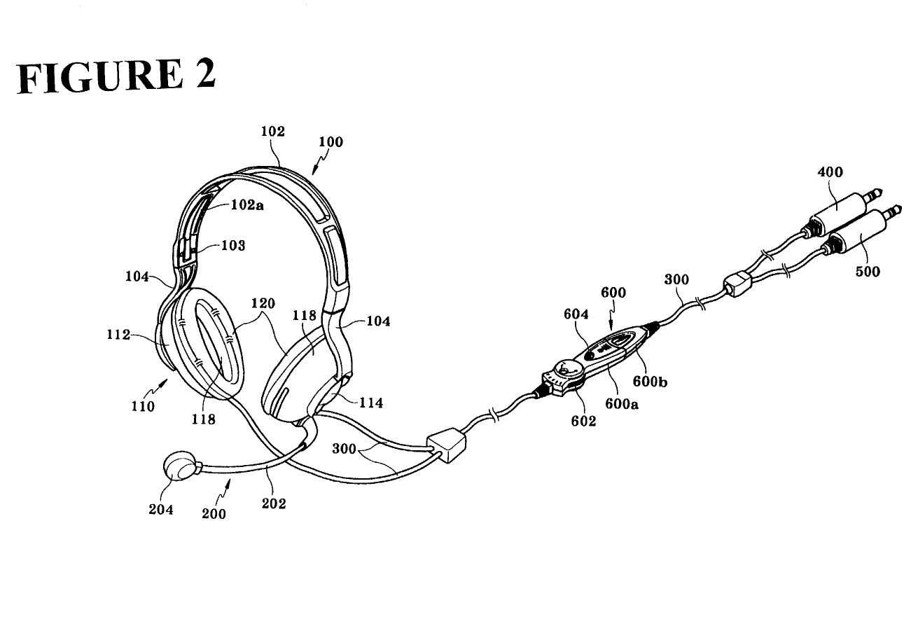

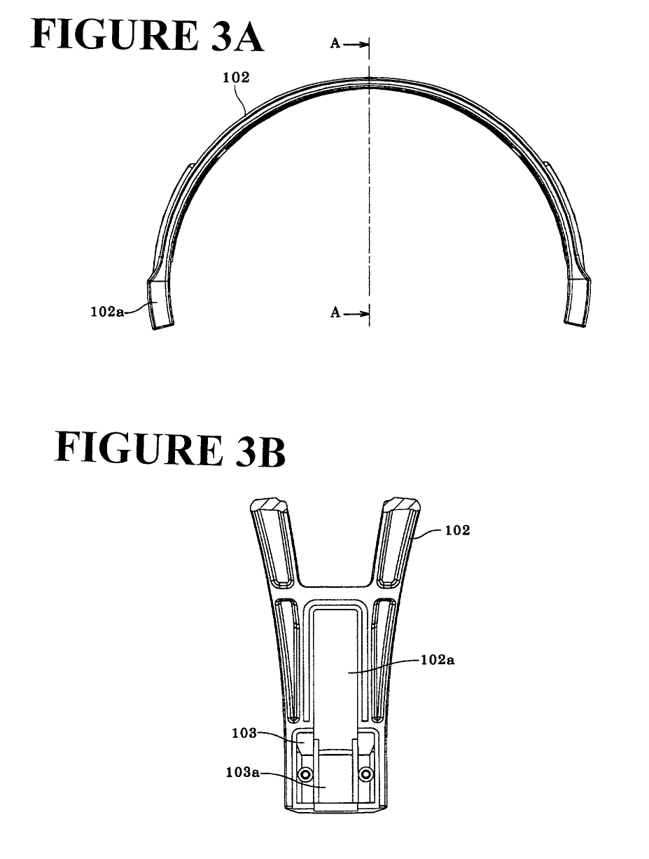

FIG. 2 illustrates a perspective view of a headset device in accordance with a preferred embodiment of the present invention. FIGS. 3a to 9b represent drawings for an explanation of components of the inventive headset device, respectively.

As shown in FIG. 2, the inventive headset device includes a headphone unit 100, a microphone unit 200 connected to the headphone unit 100, connection terminals 400 and 500 connected to the headphone unit 100 and the microphone unit 200, respectively, via cables 300, and a controller 600 mounted to the cable 300.

As the most preferred embodiment, a head-supporting type headphone is employed in the headphone unit 100.

The headphone unit 100 having the head-supporting type headphone includes a head band 102 supported by an upper or a rear portion of the head of the user, a pair of guide arms 104 inserted into both ends of the head band 102 to allow length of the headset device to be adjusted, and a pair of speaker units 110 assembled with ends of the guide arms 104, respectively.

The microphone unit 200 is provided with a connection bar 202 rotatably connected to one of the speaker units 110, and a microphone 204 fixed to a portion of the connection bar 202, so that when the head band 102 of the headphone unit 100 is positioned on the head, the microphone 204 can be located in front of a mouth of the user by properly adjusting the connecting bar 202.

The connection bar 202 is made of, e.g., plastic, a metal sheet or spring steel or other spring material, which are used in manufacturing the conventional headphone, and has a curved profile with a resilience.

Although mounted to a left side speaker unit 110 in this configuration, the microphone unit 200 may be mounted to a right side speaker unit 110.

The head band of the headphone unit 100 has a semi-circular shape with a resilience as similar to the conventional headphone and at both ends thereof slide grooves 102a into each of which the guide arm 104 can be inserted. Formed on a front portion of the slide groove 102a are planar plates 103 having tooth hook 103a for serving as a stopper resiliently depressing the guide arm 104 inserted into the slide groove 102a (see FIGS. 3a and 3b).

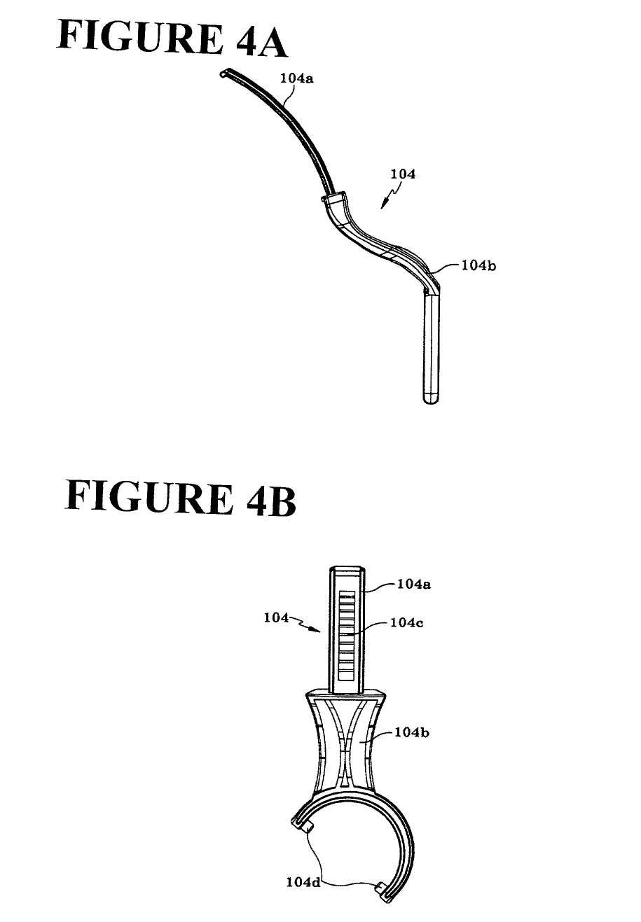

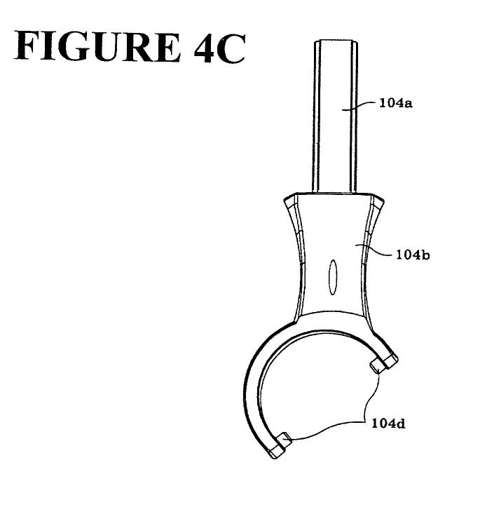

As shown in FIGS. 4a to 4c, the guide arm 104 includes a slide bar 104a inserted into the slide groove 102a of the head band 102 to allow the length of the headset device to be adjusted, and a coupling bar 104b integrally formed with the slide bar 104a and rotatably connected to the speaker unit 110 via a rotation connection 114 which will be described later.

Formed on an inner surface of the slide bar 104a is a slide tooth 104c having a plurality of stepped teeth with a predetermined separation therebetween and being cooperated with the tooth hook 103 of the planar plate 103 attached to the slide groove 102a to enable the adjustment of the length of the headset device.

The coupling bar 104b has a broader width than that of the slide bar 104a and a profile so curved as to enable the rotation of the speaker unit 110 without an interference therebetween. Further, the coupling bar 104b has a semi-circular shape at its portion to be connected to the rotation connection 114, and the semi-circular shape portion has a pair of protuberances 104d to be inserted into the rotation connection 114.

The semi-circular shape portion formed on one end of the coupling bar 104b is opened, being inclined by 40° with respect to a horizontal plane and the pair of protuberances 104d face each other, protruding to be aligned with a line.

The reason why the coupling bar 104b has such configuration in which the semi-circular shape portion is inclined at 40° relative to the horizontal plane and the coupling bar 104b is curved to be in conformity with a contour of an ear cover case 112 which will be described later is to reduce a depressing force exerted on an auricle of the ear by allowing a resilient restoring force of the head band 112 not to be concentrated on the speaker units 110 by means of the curved portion.

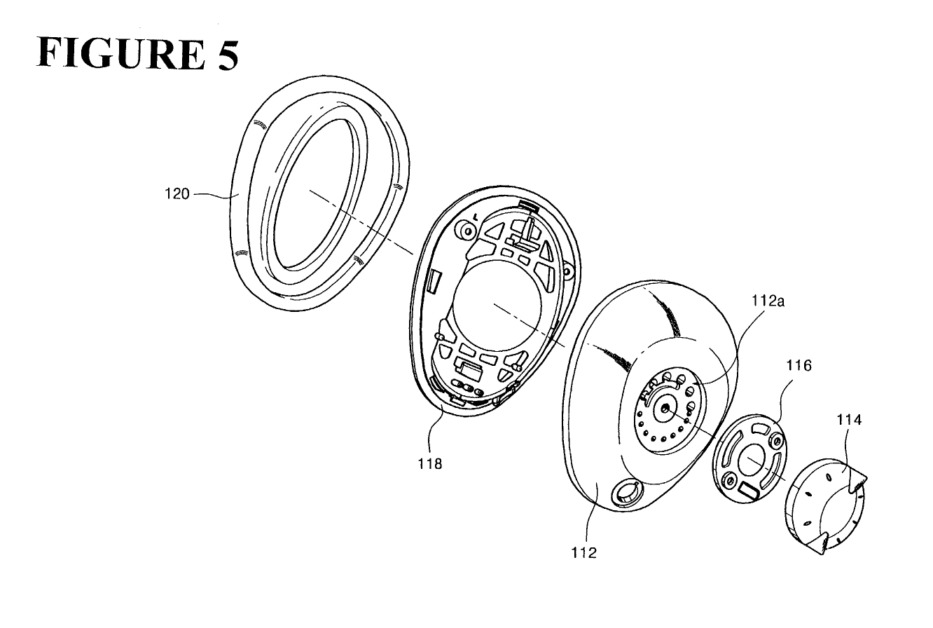

As shown in FIG. 5, the speaker unit 110 of the headphone unit 100 has the ear cover case 112 of an oval shape which can be formed, e.g., by cutting an egg-shape in a longitudinal direction, the rotation connection 114 connected to the coupling bar 104b of the guide arm 104 and mounted to an external surface of the ear cover case 112, a click cover 116 of a disk shape for guiding the rotation of the rotation connection 114, the click cover 116 positioned inside the rotation connection 114 and inserted into a circular seat 112a formed on the external surface of the ear cover case 112, along with the rotation connection 114, an ear cover 118 having a speaker 118b attached thereto, the speaker 118b mounted on an inner surface of the ear cover case 112 to be incorporated therein, and a soft cover member 120 enclosing the ear cover 118 made of leather or the like.

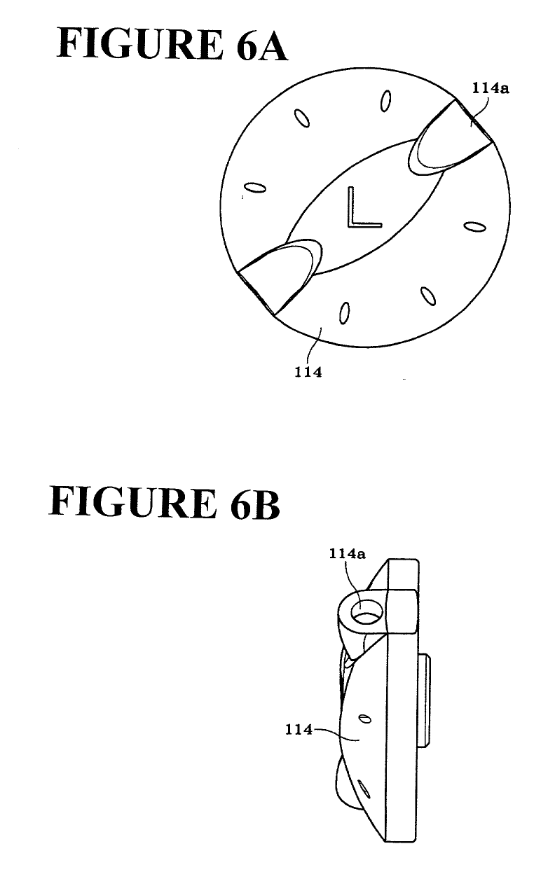

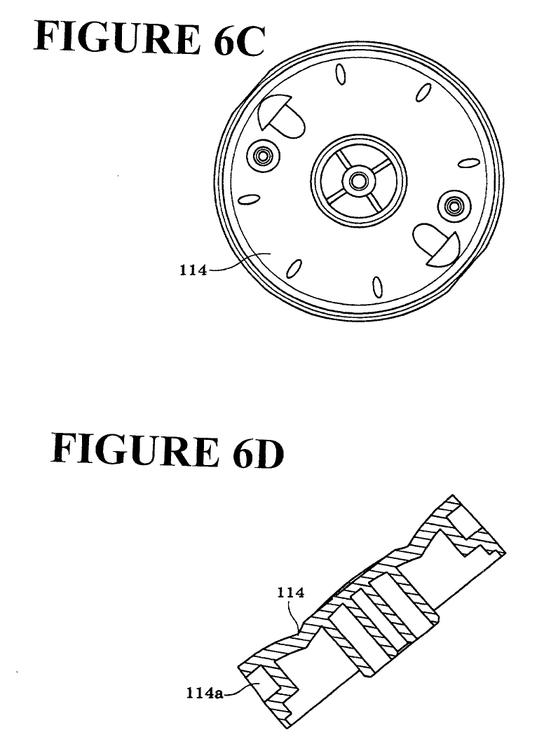

Detailed description of the component of the speaker unit 110 will be made with reference to FIGS. 6a through 9c.

The rotation connection 114 is provided with a pair of connection holes 114a symmetric in position to each other into which protuberances 104d of the coupling bar 104 are inserted, respectively. An inner diameter of the rotation connection 114 is similar to the diameter of the click cover 116 for allowing the click cover 116 to be received into the rotation connection 114. The rotation connection 114 is also provided with a bush around which a through hole 116d of the click cover 116 is positioned to be maintained thereon(see FIGS. 6a to 6d).

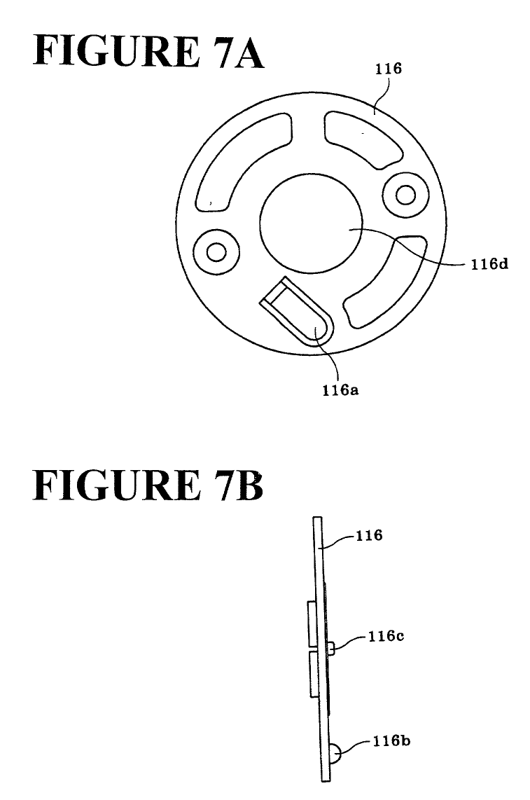

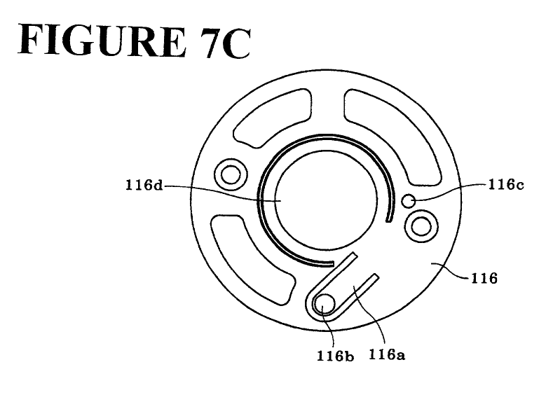

As shown in FIGS. 7a to 7c, the click cover 116 is provided with a protuberance 116b protruding from an elastic segment 116a having a resilience. The protuberance 116b is fitted into a guide slit 112b of an arcuate shape formed on the circular seat 112a formed on the external surface of the ear cover case 112 for a guide of the rotational movement of the rotation connection 114.

Formed apart from the elastic segment 116a of the click cover 116 is a stopping protuberance 116c which serves to limit the rotational movement of the rotation connection 114 by being inserted into one of a plurality of holes 112c arranged on the circular seat 112a in a circular shape with a separation therebetween.

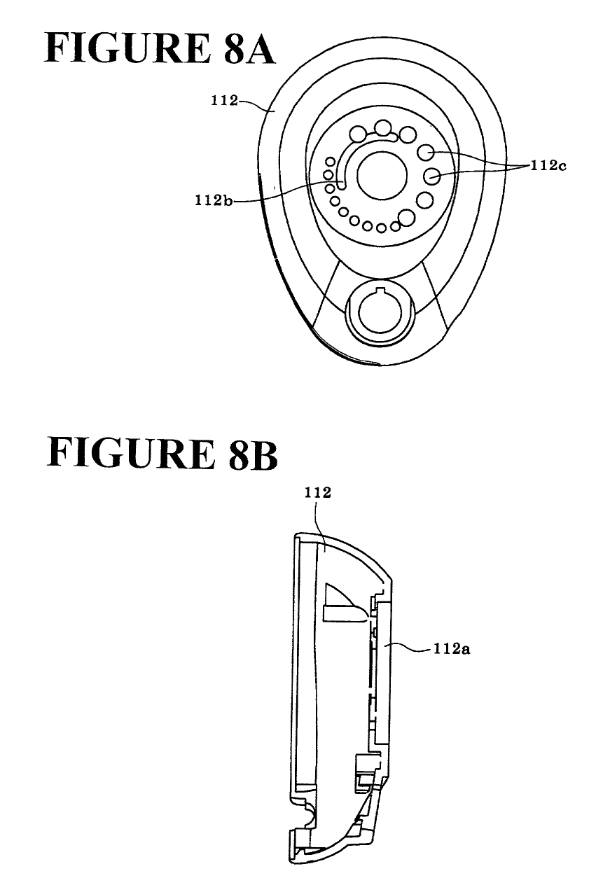

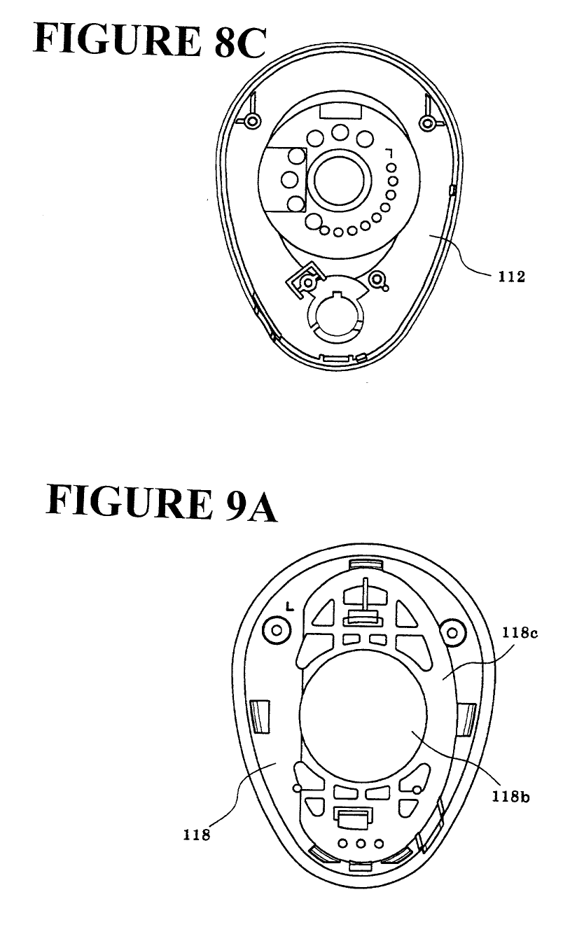

The plurality of holes 112c and the guide slit 112b are located near to each other, corresponding the positions of protuberance 116b of the elastic segment 116a and stopping protuberance 116c, respectively(see FIGS. 8a to 8c).

The rotation connection 114 together with the click cover 116 are clamped to the ear cover case 112 through the use of a thread which is introduced through a center of the circular seat 112a, after the rotation connection 114 and the click cover 116 has been seated on the circular seat 112a.

In this configuration, if the rotation connection 114 is rotated, the protuberance 116b of the elastic segment 116a is rotated along the guide slit 112b, while the stopping protuberance 116c of the click cover 116 is registered with one of the holes 112c by turns. If the rotation of the rotation connection 114 is stopped, the stopping protuberance 116c is inserted into one of the holes 112c to maintain the orientation of the rotation connection 114.

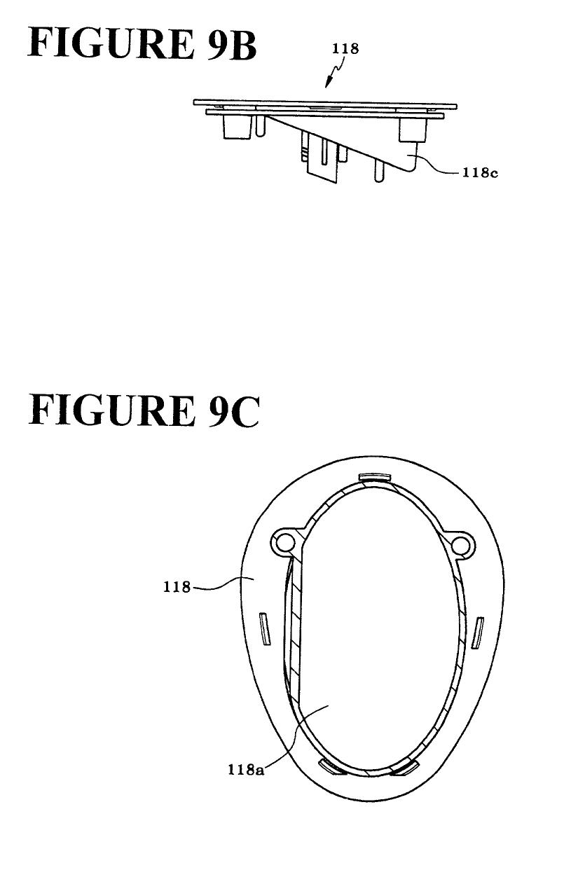

As shown in FIGS. 9a to 9c, the ear cover 118 has a size permitting enclosing an external periphery of the ear cover case 112 and a shape similar to that of the ear cover case 112, i.e., the oval shape.

The ear cover 118 has a cover groove 118a of an internally stepped shape, i.e., a shape capable of enclosing the auricle and an inclined protruding surface 118c on which the speaker 118b is mounted.

Soft cushioning member(not shown) such a sponge may be attached to the cover groove 118a of the ear cover 118.

The cables 300 are connected to both speaker units 110, respectively. The cable connected to the speaker unit 110 having the microphone unit 200 is branched into the speaker 118b and a microphone 204.

The cables 300 from the speaker units 110 are integrated into one piece of cable 300 to which the controller 600 is mounted.

The cable 300 after the controller 600 is branched into two lines to which connection terminals 400 and 500 are connected, respectively.

One of the connection terminals 400 and 500 is a headphone terminal 400 connected to a speaker socket of a sound card mounted within a computer system, while the other is a microphone terminal 500 connected to a microphone socket of the sound card.

The controller 600 is provided with a volume switch 602 for controlling a sound level output to the speaker unit 110 of the headset device, and a mute switch 604 for controlling a sound level from the microphone 204 of the headset device.

Although, e.g., a mixer program for the sound card, must be always run in the conventional manner in order to adjust the sound level output to the headset device, the adjustment of the sound level can be achieved by simply using the volume switch 602 of the controller 600 in the present invention.

Further, if the mute switch 604 is switched on by the user who is enjoying listening to the music or is speaking with somebody on the telephone, a noise occurrence in the speaker unit 110 due to the introduction of alien sound source via the microphone 204 or a transmission of unwanted audio information through the microphone 204 to a listener on the telephone can be prevented.

The controller 600 can be disassembled into a leading portion 600a and a rear portion 600b which can be assembled with each other via a standardized connection 606.

A hook 608 protruding from the rear portion 600b enables an easy assembling and disassembling of the leading portion 600a and the rear portion 600b.

The configuration in which the controller 600 can be divided into two bodies, i.e., the cable 300 is partially replacable, allows the user to easily select connection terminals 400 and 500 appropriate to the type of the socket of his newly changed sound card and replace the connection terminals 400 with the selected one by simply changing the rear portion 600b.

That is, after a plurality of rear portions 600b having different kinds of connection terminals 400 and 500 are previously prepared, the user can select a rear portion 600 having an appropriate connection terminals 400 and 500 and assemble the selected one to the leading portion 600a.

The configuration of the controller 600 described above further enables the user to move to other place, e.g., a place far from his location with the headset device still being on his head after he disconnects the rear portion 600b from the headset device.

That is, the user can freely move around after he disconnects the rear portion 600b from the leading portion 600a with its connection terminals 400 and 500 kept in the socket of the sound card.

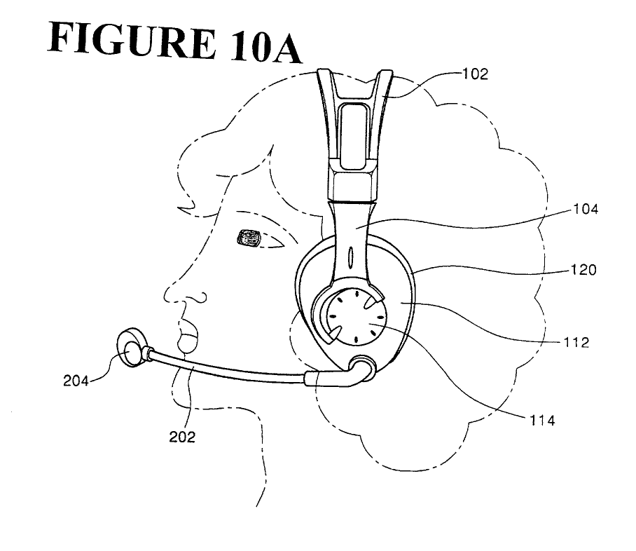

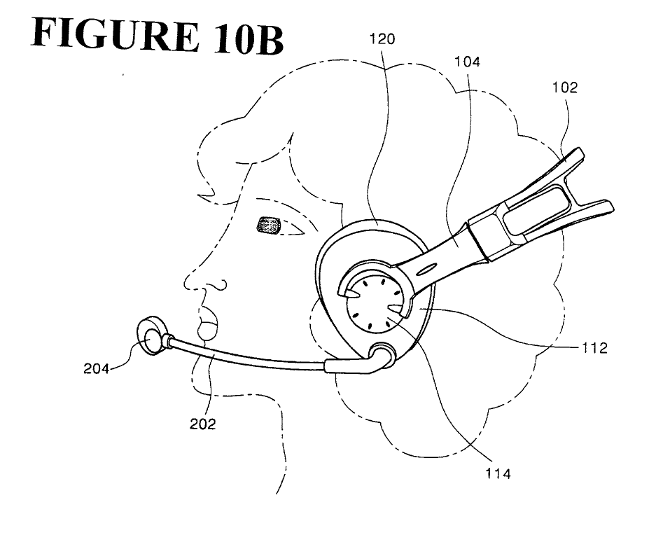

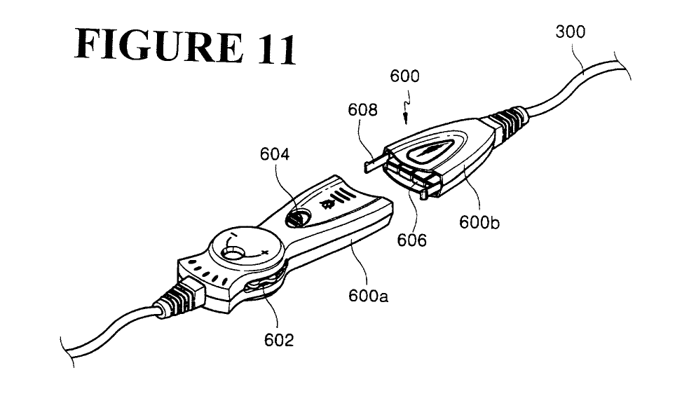

FIGS. 10a and 10b show the inventive headset devices mounted on the user's head, respectively. As shown, the user can change the position of the head band 102 without changing the orientation of the ear cover 118 through the rotation of the rotation connection 114.

In the inventive headset device constructed in this manner, the cover member 120 does not depress the auricle to allow the user to feel comfort, since the auricle of the user is received into the cover groove 118a of the ear cover 118 to be enclosed thereby.

Further, the inventive headset device can improve the problems of deformation or disorder of the user's hair style as usually shown in the conventional headset device due to the hair band, since the head band can be easily and freely repositioned.

On the other hand, the inventive headset device has the configuration in which the leading portion 600a of the controller 600 can be disassembled from the rear portion 600b and can be assembled with another rear portion 600b having different connection terminals 400 and 500, thereby enabling various kinds of connection terminals to be applicable.

In accordance with the present invention constructed in this manner, several advantages are obtained. First, the user feels comfort in that his ear does not hurt even after a long period of use and he can freely change the position of the head band, not leaving the traces on the hair caused by the head band. These are because the inventive headset device can be maintained on the head without changing the initial orientation of the speaker unit, even if the position of the head band is changed.

Further, the inventive headset device enables the user to freely move around, with his neck and head kept free, since the microphone unit can be adjusted to move in front of the mouth of the user and the head band can be in various different positions from the top position to the position near the neck of the user.

Furthermore, the inventive headset device has the configuration in which the leading portion of the controller can be disassembled from the rear portion and can be assembled with another rear portion having different connection terminals, thereby enabling various kinds of connection terminals to be applicable.

Accordingly, the present invention constructed in this manner provides a convenient headset device applicable to other various use.

Although the invention has been shown and described with respect to the preferred embodiments, it will be understood by those skilled in the art that various changes and modifications may be made without departing from the spirit and scope of the invention as defined in the following claims.

What is claimed is:

1. A headset device including a headphone unit provided with a head band, a pair of guide arms and a pair of speaker units, a microphone unit provided with a connection bar connected to one of the speaker units, and a microphone, and connection terminals connected to the speaker units and the microphone unit, respectively, via cables, the headset device characterized in that:
said head band has a resilience and a semi-circular shape to be mounted on a head of the user, the head band having at both ends thereof slide grooves, respectively;
said guide arm has a slide bar inserted into the slide groove of the head band to allow length of the headset device to be adjusted, and a coupling bar integrally formed with the slide bar and rotatably connected to the speaker unit using a pair of protuberances which protrude from a semi-circular shape portion formed on one end of the coupling bar and opened, being inclined with respect to a horizontal plane;
said speaker unit has an ear cover case of an oval shape with size capable of enclosing an auricle of the user, a rotation connection connected to the guide arm and mounted to an external surface of the ear cover case, a click cover of a disk shape for guiding the rotation of the rotation connection, the click cover positioned inside the rotation connection and inserted into a circular seat formed on the external surface of the ear cover case along with the rotation connection, an ear cover having a speaker attached thereto, the speaker mounted on an inner surface of the ear cover case to be incorporated therein, and a soft cover member enclosing the ear cover made of leather or the like; and
a controller has a function for controlling a sound level output to the speaker unit, and a function for controlling a sound level from a microphone, the controller divided into two portions.

2. The headset device of claim 1, characterized in that said click cover is provided with a protuberance protruding from an elastic segment on the click cover for allowing the rotation connection to be rotatable relative to the ear cover case, and a stopping protuberance formed away from the elastic segment; and the circular seat is provided with a plurality of holes arranged through the circular seat in a circular shape with a separation therebetween, and a guide slit of an arcuate shape formed through the circular seat formed on the external surface of the ear cover case, whereby if the rotation connection is rotated, the protuberance is rotated along the guide slit, while the stopping protuberance is registered with one of the holes by turns, and if the rotation of the rotation connection is stopped, the stopping protuberance is inserted into one of the holes to maintain an orientation of the rotation connection.

3. The headset device of claim 1, characterized in that said coupling bar is curved to be in conformity with a contour of the ear cover case to reduce a depressing force exerted on the auricle of the ear by avoiding a concentration of a resilient restoring force of the head band on the speaker units by means of the curved portion.

4. The headset device of claim 1, characterized in that said controller can be disassembled into a leading portion and a rear portion which can be assembled with each other via a standardized connection; and a plurality of rear portions and cables having different kinds of connection terminals are previously prepared.

5. The headset device of claim 1, characterized in that said controller is provided with a volume switch for controlling a sound level output to the speaker unit of the headset device, and a mute switch for controlling a sound level from the microphone of the headset device.
